(19) United States
(12) Patent Application Publication
(10) Pub. No.: US 2023/0307346 A1
(43) Pub. Date: Sep. 28, 2023

(54) SEMICONDUCTOR DEVICE AND METHOD OF MANUFACTURING THE SAME

(71) Applicant: FUJI ELECTRIC CO., LTD., Kawasaki-shi (JP)

(72) Inventors: Yasuaki HOZUMI, Matsumoto-city (JP); Fumihiko MOMOSE, Higashi-chikuma-gun (JP); Natsuki TAKEISHI, Matsumoto-city (JP); Ryoto UCHIYAMA, Matsumoto-city (JP)

(73) Assignee: FUJI ELECTRIC CO., LTD., Kawasaki-shi (JP)

(21) Appl. No.: 18/160,525

(22) Filed: Jan. 27, 2023

(30) Foreign Application Priority Data
Mar. 22, 2022 (JP) 2022-045846

(51) Int. Cl. H01L 23/498; H01L 23/00; H01L 21/428; H01L 21/02

(52) U.S. Cl. CPC H01L 23/49838; H01L 24/32; H01L 24/83; H01L 21/428; H01L 21/02244; H01L 2224/83815; H01L 2224/32113; H01L 2224/32225; H01L 2924/1632

(57) ABSTRACT

A method of manufacturing a semiconductor device, includes; preparing an insulated circuit substrate including a circuit layer having a main surface and a side surface inclined to a normal direction of the main surface; irradiating the side surface of the circuit layer with a laser beam so as to roughen at least a part of the side surface of the circuit layer and provide an oxide film on the roughened side surface of the circuit layer; and bonding a semiconductor chip to the main surface of the circuit layer via a solder layer.

### CROSS-REFERENCE TO RELATED APPLICATION

This application claims benefit of priority under 35 USC 119 based on Japanese Patent Application No. 2022-045846 filed on Mar. 22, 2022, the entire contents of which are incorporated by reference herein.

### BACKGROUND OF THE INVENTION

### 1. Field of the Invention

The present invention relates to a semiconductor device and a method of manufacturing the semiconductor device

### 2. Description of the Related Art

Semiconductor devices are known that have a structure in which a semiconductor chip is bonded onto a circuit layer (a circuit pattern) of an insulated circuit substrate by soldering. To deal with solder wettability to avoid a spread of the solder on the circuit layer, a first means (laser resist) is known that irradiates a flat part of the top surface of the circuit layer with a laser beam along the circumference of the solder-bonded part and oxidizes and roughens the surface so as to decrease the wettability of the solder. A second means is also known that surrounds the circumference of the solder-bonded part by a wire at the flat part of the top surface of the circuit layer so as to physically avoid the spread of the solder. A third means is also known that provides slits at the flat part of the top surface of the circuit layer so as to physically avoid a contact of the soldering material between the respective semiconductor chips.

JP 2005-268821 A discloses a ceramic circuit substrate provided with a projecting part that is a metal-brazed layer extending from an outer edge of a metal plate so as to have an inclined surface along the entire circumference of the end surface of the metal plate, in which the projecting part has a maximum surface roughness Rmax of 5 micrometers to 50 micrometers. JP 2007-311526 A discloses a substrate for a power module integrated with a circuit layer by metal brazing on a surface of a ceramic plate, in which a side surface of the outer surface of the circuit layer extending upward from the surface of the ceramic plate in the substantially vertical direction is provided with an oxide film.

WO 2019/003725 A1 discloses that a surface roughness of a side surface of a metal plate is set in a range of 0.3 micrometers to 1.0 micrometers so as to decrease wettability of brazing material. JP 2021-145081 A discloses a semiconductor device including a conductor part, a semiconductor chip, a soldering material, and hollow parts, in which the hollow parts each have an inclined inner surface that is subjected to surface roughening treatment.

JP 2021-039962 A discloses that a power semiconductor chip is arranged at an upper part of a conductive plate, and the other part of the top surface of the conductive plate not provided with the power semiconductor chip is provided with dotted holes by laser irradiation.

The insulated circuit substrate needs to keep an insulating distance between the lands of the circuit layers. However, the respective semiconductor chips are inevitably arranged at positions adjacent to the edge of the top surface of the circuit layer when the respective semiconductor chips are packaged with high density, which would prevent the insulated circuit substrate from keeping the insulating distance, since the soldering material bonding the semiconductor chips spreads toward grooves between the circuit layers. Further, since the respective semiconductor chips need to be arranged at the positions adjacent to the edge of the top surface of the circuit layer, the conventional first to third means described above for dealing with the wettability of the solder cannot sufficiently ensure a space for roughening the surface, arranging the wires, or providing the slits at the flat part on the top surface of the respective circuit layers.

### SUMMARY OF THE INVENTION

In view of the foregoing problems, the present invention provides a semiconductor device having a configuration capable of achieving high-density packaging while decreasing solder wettability to avoid a spread of solder for bonding an insulated circuit substrate and a semiconductor chip to each other, and a method of manufacturing the same.

An aspect of the present invention inheres in a semiconductor device including: an insulated circuit substrate including a circuit layer having a main surface and a side surface inclined to a normal direction of the main surface; a semiconductor chip provided to be opposed to the main surface of the circuit layer; and a solder layer provided to bond the semiconductor chip and the circuit layer to each other, wherein a surface roughness of at least a part of the side surface of the circuit layer is greater than a surface roughness of the main surface of the circuit layer at a position opposed to the semiconductor chip.

Another aspect of the present invention inheres in a method of a semiconductor device including: preparing an insulated circuit substrate including a circuit layer having a main surface and a side surface inclined to a normal direction of the main surface; irradiating the side surface of the circuit layer with a laser beam so as to roughen at least a part of the side surface of the circuit layer and provide an oxide film on the roughened side surface of the circuit layer; and bonding a semiconductor chip to the main surface of the circuit layer via a solder layer.

### BRIEF DESCRIPTION OF THE DRAWINGS

FIG. 1 is a plan view illustrating a main part of a semiconductor device according to a first embodiment;

FIG. 2 is a cross-sectional view taken along line A-A′ in FIG. 1;

FIG. 3 is an enlarged cross-sectional view illustrating region B in FIG. 2;

FIG. 4 is a cross-sectional view for explaining a method of manufacturing the semiconductor device according to the first embodiment;

FIG. 5 is a cross-sectional view continued from FIG. 4 for explaining the method of manufacturing the semiconductor device according to the first embodiment;

FIG. 6 is a cross-sectional view illustrating a semiconductor device of a comparative example;

FIG. 7 is a cross-sectional view illustrating a semiconductor device of another comparative example;

FIG. 8 is a cross-sectional view illustrating a semiconductor device of still another comparative example;

FIG. 9 is a cross-sectional view illustrating a semiconductor device of still another comparative example;

FIG. 10 is a cross-sectional view illustrating a semiconductor device according to a second embodiment;

FIG. 11 is a cross-sectional view illustrating a semiconductor device according to a third embodiment; and

FIG. 12 is a plan view illustrating a main part of a semiconductor device according to a fourth embodiment.

### DETAILED DESCRIPTION

With reference to the Drawings, first to fourth embodiments of the present invention will be described below.

In the Drawings, the same or similar elements are indicated by the same or similar reference numerals. The Drawings are schematic, and it should be noted that the relationship between thickness and planer dimensions, the thickness proportion of each layer, and the like are different from real ones. Moreover, in some drawings, portions are illustrated with different dimensional relationships and proportions. The embodiments described below merely illustrate schematically devices and methods for specifying and giving shapes to the technical idea of the present invention, and the span of the technical idea is not limited to materials, shapes, structures, and relative positions of elements described herein.

In the embodiment, a “first main electrode region” of a semiconductor chip is assigned to a semiconductor region which is a source region or a drain region in a field-effect transistor (FET) or a static induction transistor (SIT). The first main electrode region is assigned to a semiconductor region which is an emitter region or a collector region in an insulated-gate bipolar transistor (IGBT). The first main electrode region is assigned to a semiconductor region which is an anode region or a cathode region in a static induction (SI) thyristor, a gate turn-off (GTO) thyristor or a diode. A “second main electrode region” of the semiconductor chip is assigned to a semiconductor region which is not assigned as the first main electrode region and will be the source region or the drain region in the FET or the SIT, the emitter region or the collector region in the IGBT, and the anode region or the cathode region in the SI thyristor, the GTO thyristor or the diode. That is, when the “first main electrode region” is the source region, the “second main electrode region” means the drain region. When the “first main electrode region” is the emitter region, the “second main electrode region” means the collector region. When the “first main electrode region” is the anode region, the “second main electrode region” means the cathode region.

Additionally, definitions of directions such as “upper”, “lower”, “upper and lower”, “left”, “right”, and “left and right” in the following description are simply definitions for convenience of description, and do not limit the technological concept of the present invention. For example, when observing an object rotated by 90 degrees, the “upper and lower” are converted to “left and right” to be read, and when observing an object rotated by 180 degrees, the “upper and lower” are read reversed, which should go without saying.

### First Embodiment

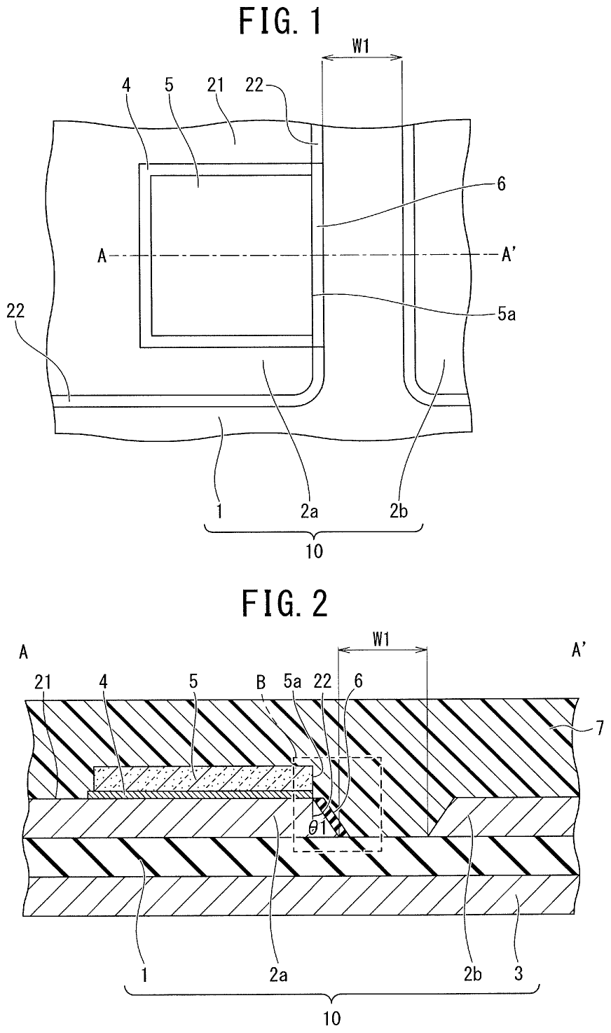

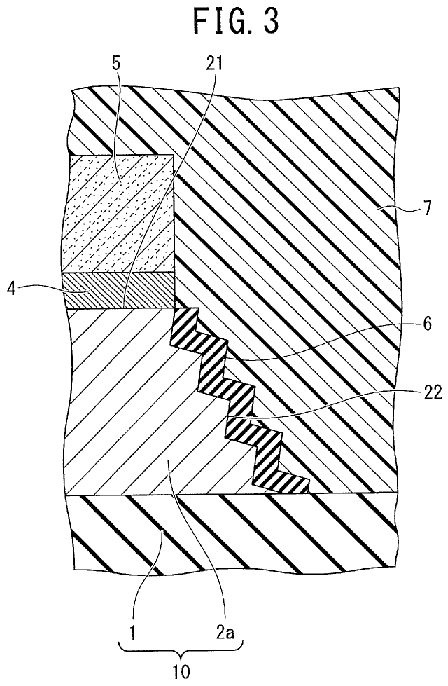

FIG. 1 is a plan view illustrating a main part of a semiconductor device according to a first embodiment, and FIG. 2 is a cross-sectional view taken along line A-A′ in FIG. 1. FIG. 1 omits the illustration of a sealing member 7 illustrated in FIG. 2. As illustrated in FIG. 1 and FIG. 2, the semiconductor device according to the first embodiment is a power module including an insulated circuit substrate 10, a semiconductor chip (a power semiconductor chip) 5 provided to be opposed to one of main surfaces (the top surface) of the insulated circuit substrate 10, and a solder layer 4 interposed between the insulated circuit substrate 10 and the semiconductor chip 5 so as to bond the insulated circuit substrate 10 and the semiconductor chip 5 together.

The insulated circuit substrate 10 has a rectangular planar shape, for example. The insulated circuit substrate 10 is a direct copper bonded (DCB) substrate or an active metal brazed (AMB) substrate, for example. The insulated circuit substrate 10 includes an insulating substrate 1, circuit layers (circuit patterns) 2a and 2b that are conductor layers deposited on one of the main surfaces (the top surface) of the insulating substrate 1, and a heat-releasing layer 3 that is a conductive layer deposited on the other main surface (the bottom surface) of the insulating substrate 1.

The insulating substrate 1 is a ceramic substrate made from aluminum oxide (Al₂O₃), aluminum nitride (AlN), silicon nitride (Si₃N₄) or boron nitride (BN), or a resin insulating substrate including polymer material, for example. The circuit layers 2a and 2b and the heat-releasing layer 3 are each conductor foil made from copper (Cu) or aluminum (Al), for example.

A thickness of the respective circuit layers 2a and 2b is set in a range of about 0.1 millimeters or greater and 0.5 millimeters or less, for example, but is not limited to this range. The pattern shape, the arrangement position, and the number of the circuit layers 2a and 2b are determined as appropriate. The circuit layers 2a and 2b are arranged separately from each other at an insulating distance W1 with a pattern groove interposed. The insulating distance W1 is set in a range of about 0.5 millimeters or greater and 1.0 millimeters or less, for example, but is not limited to this range.

Although not illustrated, a metal base or a heat-releasing fin may be provided on the other main surface (the bottom surface) of the insulated circuit substrate 10 via a compound such as thermal interface material (TIM).

The solder layer 4 is made from lead-free solder such as thin-antimony-based (Sn—Sb), thin-copper-based (Sn—Cu), thin-copper-silver-based (Sn—Cu—Ag), tin-silver-based (Sn—Ag), thin-silver-copper-based (Sn—Ag—Cu), thin-silver-bismuth-copper-based (Sn—Ag—Bi—Cu), tin-indium-silver-bismuth-based (Sn—In—Ag—Bi), tin-zinc-based (Sn—Zn), tin-zinc-bismuth-based (Sn—Zn—Bi), tin-bismuth-based (Sn—Bi), or tin-indium-based (Sn—In) solder, or leaded solder such as tin-lead-based (Sn-Pn) solder, for example.

The semiconductor chip 5 is a semiconductor element such as an insulated gate bipolar transistor (IGBT), a field-effect transistor (FET), a static induction (SI) thyristor, a gate turn-off (GTO) thyristor, or a freewheeling diode (FWD), for example. The semiconductor chip 5 may be either a unipolar device or a bipolar device. The semiconductor chip 5 may be a silicon (Si) substrate, or may be a compound semiconductor substrate of a wide-bandgap semiconductor made from silicon carbide (SiC), gallium nitride (GaN), gallium arsenide (GaAs), gallium oxide (Ga₂O₃), or diamond (C), for example.

When the semiconductor chip 5 is a MOSFET, for example, the semiconductor chip 5 includes a first main electrode (a drain electrode) on the bottom surface side, and a control electrode (a gate electrode) and a second main electrode (a source electrode) on the top surface side. The drain electrode of the semiconductor chip 5 is bonded to the circuit layer 2a of the insulated circuit substrate 10 via the solder layer 4. The gate electrode and the source electrode of the semiconductor chip 5 are electrically connected to external elements via bonding wires, lead frames, or pin-shaped terminals (not illustrated), for example.

While FIG. 1 and FIG. 2 illustrate the case of using the single semiconductor chip 5, the number of the semiconductor chips can be determined as appropriate depending on a current capacity of the power module, for example, and the power module may include two or more semiconductor chips. When including two or more semiconductor chips, the power module may include either the same kind of semiconductor chips or different kinds of semiconductor chips.

As illustrated in FIG. 2, the insulated circuit substrate 10, the solder layer 4, and the semiconductor chip 5 are sealed with the sealing member 7. The sealing member 7 to be used can be made from resin material such as thermosetting resin having high heat resistance. Specific examples of resin material include epoxy resin, maleimide resin, and cyanate resin.

The insulated circuit substrate 10, the solder layer 4, the semiconductor chip 5, and the sealing member 7 are housed in a case (not illustrated). The case is made from thermoplastic resin such as polyphenylene sulfide (PPS), polybutylene terephthalate (PBT), polybutylene succinate (PBS), polyamide, and acrylonitrile butadiene styrene (ABS), for example.

The following explanations are made while focusing on one (the circuit layer 2a) of the two circuit layers 2a and 2b of the insulated circuit substrate 10 on which the semiconductor chip 5 is deposited. The circuit layer 2a includes a main surface (a top surface) 21 substantially parallel to the top surface of the insulating substrate 1, and a side surface 22 integrated with the top surface 21 and inclined at a predetermined angle θ1 to the normal direction of the top surface 21. The angle θ1 is set in a range of about greater than 0 degrees and 45 degrees or smaller, for example.

The side surface 22 of the circuit layer 2a is provided with an oxide film 6. The oxide film 6 is formed such that the side surface 22 of the circuit layer 2a is heated by irradiation with a laser beam (the specific explanations are made below). The provision of the oxide film 6, which has low wettability of solder, can avoid a spread of the solder layer 4 provided on the top surface 21 of the circuit layer 2a upon the assembly of the semiconductor device.

A thickness of the oxide film 6 is greater than that of a native oxide film, and is set to about 2 nanometers or greater, for example. The thickness of the oxide film 6 may be set to about 10 nanometers or greater, or set to about 50 nanometers or greater. The thickness of the oxide film 6 may be decreased afterward by hydrogen reduction upon reflow soldering in the process of assembling the semiconductor device. For example, the thickness of the oxide film 6 immediately after being formed may be about 50 nanometers, and the thickness of the oxide film 6 after the completion of the semiconductor device may be about 10 nanometers. The oxide film 6 does not necessarily remain but may be removed by the hydrogen reduction during the reflow soldering in the process of assembling the semiconductor device or by a process that can remove the oxide film 6, for example. When the oxide film 6 does not remain, the side surface 22 of the circuit layer 2a may be in contact with the sealing member 7.

FIG. 3 is an enlarged cross-sectional view illustrating region B surrounding a part adjacent to the side surface 22 of the circuit layer 2a in FIG. 2. As illustrated in FIG. 3, the side surface 22 of the circuit layer 2a provided with the oxide film 6 is roughened by the irradiation with the laser beam. The side surface 22 of the circuit layer 2a is corrugated, and the oxide film 6 has the cross section having the corrugated parts. FIG. 3 schematically illustrates the state in which the side surface 22 of the circuit layer 2a is roughened, and the oxide film 6 is provided on the roughened surface, but the present embodiment is not intended to be limited to the shape of the side surface 22 of the circuit layer 2a and the shape of the oxide film 6 as illustrated in FIG. 3.

A surface roughness of the side surface 22 of the circuit layer 2a provided with the oxide film 6, which corresponds to a surface roughness of the oxide film 6, is greater than a surface roughness of the top surface 21 of the circuit layer 2a not roughened at the position opposed to the semiconductor chip 5. An arithmetic mean roughness Ra of the side surface 22 of the circuit layer 2a provided with the oxide film 6 is set to about 25 micrometers or greater, for example, and may be set to about 30 micrometers or greater. Roughening the side surface 22 of the circuit layer 2a provided with the oxide film 6 decreases the solder wettability, so as to sufficiently avoid or decrease a spread of the solder layer 4 deposited on the top surface 21 of the circuit layer 2a upon the assembly of the semiconductor device. The greater surface roughness of the side surface 22 of the circuit layer 2a is preferable since the solder layer 4 is prevented from spreading more reliably.

When the oxide film 6 does not remain, the surface roughness of the side surface 22 of the circuit layer 2a itself is greater than the surface roughness of the top surface 21 of the circuit layer 2a not roughened at the position opposed to the semiconductor chip 5. The arithmetic mean roughness Ra of the side surface 22 of the circuit layer 2a itself is set to about 25 micrometers or greater, for example, and may be set to about 30 micrometers or greater.

As illustrated in FIG. 1, the semiconductor chip 5 has a rectangular shape in the planar pattern, and the right side 5a that is one of the sides of the rectangle of the semiconductor chip 5 is located at the edge of the top surface 21 of the circuit layer 2a. The semiconductor chip 5 may be arranged such that the right side 5a is arranged away from the edge of the top surface 21 of the circuit layer 2a so as to be located on the inner side of the edge of the top surface 21 of the circuit layer 2a. While FIG. 1 illustrates the case in which the solder layer 4 protrudes to the outside of the semiconductor chip 5, the edge of the solder layer 4 may conform to the edge of the semiconductor chip 5, or may be located on the inside of the semiconductor chip 5.

The oxide film 6 is selectively provided at a part of the side surface 22 of the circuit layer 2a opposed to the right side 5a of the semiconductor chip 5. The oxide film 6 may be provided in a region longer than the right side 5a of the semiconductor chip 5, for example. The surface roughness of the roughened side surface 22 of the circuit layer 2a provided with the oxide film 6 is greater than the surface roughness of the side surface 22 of the circuit layer 2a not roughened or not provided with the oxide film 6. When the oxide film 6 is not provided, the surface roughness of the roughened side surface 22 of the circuit layer 2a at the position corresponding to the oxide film 6 illustrated in FIG. 1 is greater than the surface roughness of the side surface 22 of the circuit layer 2a not roughened at the position not corresponding to the oxide film 6.

<Method of Manufacturing Semiconductor Device>

An example of a method of manufacturing (assembling) the semiconductor device according to the first embodiment is described below.

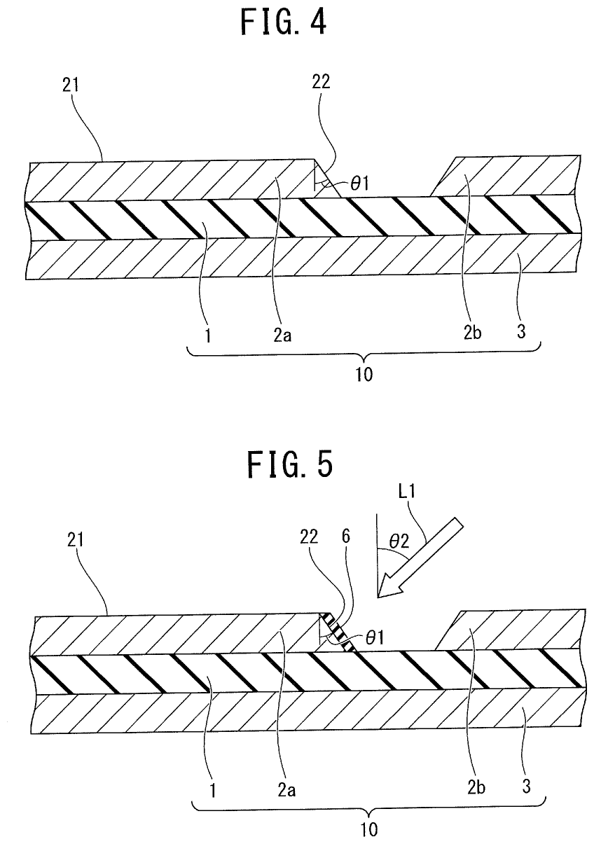

First, as illustrated in FIG. 4, the insulated circuit substrate 10 is prepared. The insulated circuit substrate 10 includes the insulating substrate 1, the circuit layers 2a and 2b provided on the top surface side of the insulating substrate 1, and the heat-releasing layer 3 provided on the bottom surface side of the insulating substrate 1. The circuit layer 2a has the top surface 21 and the side surface 22 integrated with the top surface 21 and inclined at the predetermined angle θ1 to the normal direction of the top surface 21.

Next, as illustrated in FIG. 5, the side surface 22 of the circuit layer 2a is irradiated with a laser beam L1 so as to roughen and heat the side surface 22 of the circuit layer 2a to provide the oxide film 6 on the roughened side surface 22 of the circuit layer 2a. This step leads the surface roughness of the roughened side surface 22 of the circuit layer 2a provided with the oxide film 6 to be greater than the surface roughness of the top surface 21 of the circuit layer 2a not roughened at the position opposed to the semiconductor chip 5. The oxide film 6 is provided to have the thickness that is sufficient for the reflow soldering described below and is about 10 nanometers or greater, for example, or may be about 50 nanometers or greater. The thickness of the oxide film 6 can be adjusted by the regulation of irradiating power of the laser beam for providing the oxide film 6.

The laser beam L1 may be a fiber laser, a YAG laser, or a carbon dioxide (CO₂) laser, for example. The regulation of the irradiation power of the laser beam L1 can adjust the thickness of the oxide film 6. The regulation of the irradiation power or a spot diameter of the laser beam L1 can also adjust the surface roughness of the side surface 22 of the circuit layer 2a.

An irradiation angle θ2 of the laser beam L1 to the normal direction of the top surface 21 of the circuit layer 2a is set in a range of about 0 degrees or greater and 45 degrees or smaller. The laser beam L1 may be emitted in the normal direction of the top surface 21 of the circuit layer 2a, or may be emitted in a direction inclined toward the normal direction of the side surface 22 of the circuit layer 2a with respect to the normal direction of the top surface 21 of the circuit layer 2a.

The laser beam L1 may be emitted to the side surface 22 of the circuit layer 2a in the substantially orthogonal direction. When the angle θ1 of the side surface 22 inclined to the normal direction of the top surface 21 of the circuit layer 2a is 45 degrees, for example, the irradiation angle θ2 of the laser beam L1 to the normal direction of the top surface 21 of the circuit layer 2a is set to 45 degrees. The laser beam L1 may be emitted in a direction inclined to the side surface 22 of the circuit layer 2a. When the angle θ1 of the side surface 22 inclined to the normal direction of the top surface 21 of the circuit layer 2a is 45 degrees, for example, the irradiation angle θ2 of the laser beam L1 may be set to 0 degrees so that the laser beam L1 is emitted in the normal direction of the top surface 21 of the circuit layer 2a.

Alternatively, the pulsed laser beam L1 may be led to scan the side surface 22 of the circuit layer 2a to intermittently form dotted holes so as to continuously provide the oxide film 6 around the dotted holes. Alternatively, the laser beam L1 may be led to scan the side surface 22 of the circuit layer 2a not in the pulsed state but straightly to form a line-shaped groove so as to continuously provide the oxide film 6 around the groove. Alternatively, the laser beam L1 may be led to straightly scan the side surface 22 of the circuit layer 2a once in the upper-lower direction in FIG. 1 or may be led to scan several times in parallel, or may be led to scan the side surface 22 of the circuit layer 2a in a zigzag state in the planar pattern in FIG. 1.

Next, a soldering material for forming the solder layer 4 is put on the top surface 21 of the circuit layer 2a of the insulated circuit substrate 10. The soldering material may be a plate-like preform material or cream solder, for example. The semiconductor chip 5 is further deposited on the top surface 21 of the circuit layer 2a of the insulated circuit substrate 10 via the soldering material.

Next, the stacked body of the insulated circuit substrate 10, the soldering material, and the semiconductor chip 5 is put into a heating furnace. Heating and melting the soldering material in the heating furnace forms the solder layer 4 so as to bond the insulated circuit substrate 10 and the semiconductor chip 5 to each other. Roughening the side surface 22 of the circuit layer 2a provided with the oxide film 6 can decrease the solder wettability to avoid a spread of the solder layer 4 toward the side surface 22 of the circuit layer 2a. The heating conditions are preferably set to a temperature in a range of about 280 degrees or higher and 350 degrees or lower under the hydrogen atmosphere, and a time for a bonding-peak temperature in a range of about 1 minute or longer and 10 minutes or shorter, for example, so as to decrease the wettability of the solder layer 4 to sufficiently avoid the spread of the solder layer 4.

The thickness of the oxide film 6 is preferably kept at about 10 nanometers or greater during the period from the point at which the heating treatment in the heating furnace is started to the point at which the spread of the solder layer 4 is completely stopped. Keeping the thickness of the oxide film 6 at about 10 nanometers or greater can decrease the wettability of the solder layer 4 to sufficiently avoid the spread of the solder layer 4. The greater thickness of the oxide film 6 is preferable so as to avoid the spread of the solder layer 4 more reliability. Upon the heating treatment under the hydrogen atmosphere, which reduces the oxide film 6, the thickness of the oxide film 6 immediately after being formed is preferably set to 50 nanometers or greater, for example, in view of the reduced amount of the oxide film 6. Setting the thickness of the oxide film 6 to 50 nanometers or greater can keep the thickness sufficient to avoid the spread of the solder layer 4 when the heating treatment is executed under the hydrogen atmosphere afterward. A step of removing the oxide film 6 may be executed after the formation of the solder layer 4.

Next, bonding wires, lead frames, or pin-shaped terminals are connected to the semiconductor chip 5. The stacked body of the insulated circuit substrate 10, the solder layer 4, and the semiconductor chip 5 is placed inside a case, and the case is then filled with the sealing member 7 so as to seal the insulated circuit substrate 10 and the semiconductor chip 5 together. A heat-releasing base or a heat-releasing fin is attached to the bottom surface side of the insulated circuit substrate 10. The semiconductor device according to the first embodiment is thus completed through the procedure as described above.

### COMPARATIVE EXAMPLES

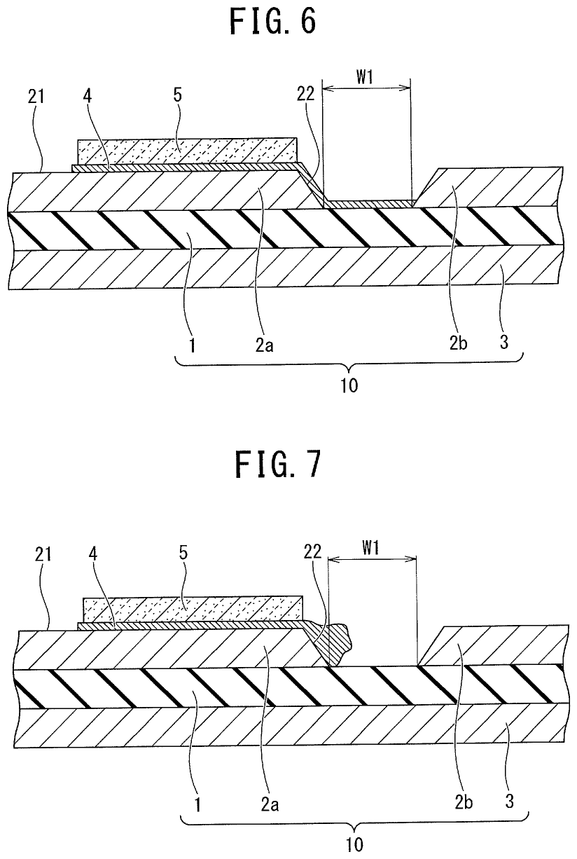

A semiconductor device of a comparative example is described below with reference to FIG. 6 to FIG. 9. The semiconductor device of the comparative example illustrated in FIG. 6 and FIG. 7 having a structure with no measures taken to deal with the solder wettability differs from the semiconductor device according to the first embodiment in which the side surface 22 of the circuit layer 2a is not provided with the oxide film or not roughened. The semiconductor device of the comparative example with the structure not dealing with the solder wettability illustrated in FIG. 6 causes the solder layer 4 to spread toward the pattern groove between the circuit layers 2a and 2b through the side surface 22 of the circuit layer 2a during the assembly, which cannot sufficiently keep the insulating distance W1, resulting in a short circuit between the circuit layers 2a and 2b. The semiconductor device of the comparative example illustrated in FIG. 7 also causes a projection on the side surface 22 of the circuit layer 2a because of the spread of the solder layer 4, which cannot sufficiently keep the insulating distance W1 either.

In contrast to the semiconductor device of the comparative example illustrated in FIG. 6 and FIG. 7, the semiconductor device and the method of manufacturing the semiconductor device according to the first embodiment can decrease the solder wettability to sufficiently avoid the spread of the solder layer 4 on the side surface 22 of the circuit layer 2a, since the side surface 22 of the circuit layer 2a provided with the oxide film 6 is roughened during the reflow soldering of the solder layer 4.

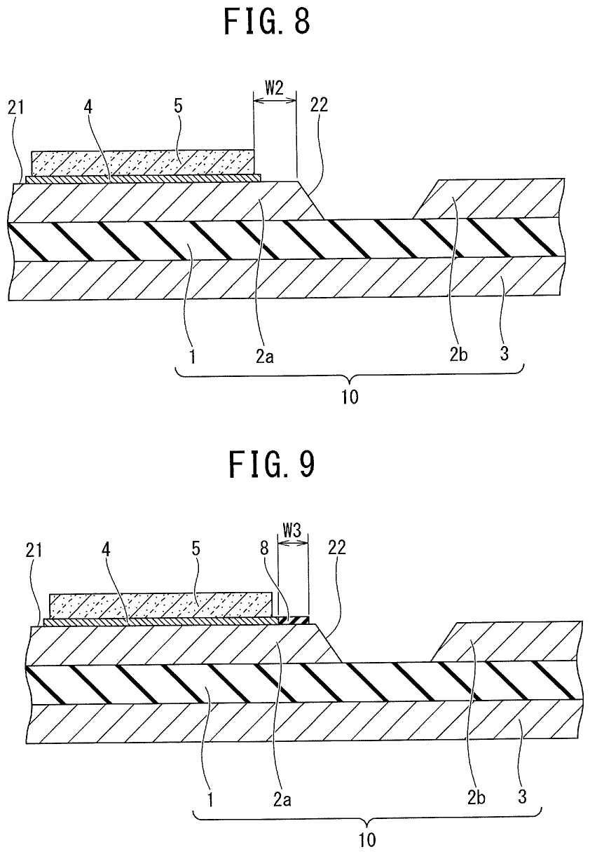

A semiconductor device of another comparative example illustrated in FIG. 8 having a structure with no measures taken to deal with the solder wettability differs from the semiconductor device according to the first embodiment in which the side surface 22 of the circuit layer 2a is not provided with the oxide film or not roughened. The semiconductor device of the comparative example with the structure not dealing with the solder wettability illustrated in FIG. 8 needs to arrange the semiconductor chip 5 at a position away from the edge of the top surface 21 of the circuit layer 2a with a predetermined distance W2 kept in order to avoid the spread of the solder layer 4 toward the side surface 22 of the circuit layer 2a, which impedes the packaging with high density.

In contrast to the semiconductor device of the comparative example illustrated in FIG. 8, the semiconductor device and the method of manufacturing the semiconductor device according to the first embodiment can decrease the solder wettability to sufficiently avoid the spread of the solder layer 4 on the side surface 22 of the circuit layer 2a, since the side surface 22 of the circuit layer 2a provided with the oxide film 6 is roughened during the reflow soldering of the solder layer 4. This configuration can arrange the semiconductor chip 5 immediately close to the edge of the top surface 21 of the circuit layer 2a, so as to achieve the packaging at high density. When the semiconductor chip 5 is not necessarily arranged immediately close to the edge of the top surface 21 of the circuit layer 2a, the flexibility of the arrangement of the semiconductor chip 5 can be increased.

A semiconductor device of still another comparative example illustrated in FIG. 9 differs from the semiconductor device according to the first embodiment in that the top surface 21 of the circuit layer 2a is irradiated with a laser beam so as to be roughened and provided with the oxide film 8 in order to deal with the solder wettability. The semiconductor device of the comparative example illustrated in FIG. 9 needs to keep a predetermined distance (space) W3 for forming the oxide film 8 on the top surface 21 of the circuit layer 2a, which prevents the arrangement of the semiconductor chip 5 at the edge of the top surface 21 of the circuit layer 2a and impedes the packaging with high density. The semiconductor device of the comparative example, if provided with wires or slits on the top surface 21 of the circuit layer 2a to deal with the solder wettability, also has the same problems as in the case described above.

In contrast to the semiconductor device of the comparative example illustrated in FIG. 9, the semiconductor device and the method of manufacturing the semiconductor device according to the first embodiment can decrease the solder wettability to sufficiently avoid the spread of the solder layer 4 on the side surface 22 of the circuit layer 2a, since the side surface 22 of the circuit layer 2a provided with the oxide film 6 is roughened during the reflow soldering of the solder layer 4. This configuration can arrange the semiconductor chip 5 immediately close to the edge of the top surface 21 of the circuit layer 2a, so as to achieve the packaging at high density.

Further, the semiconductor device and the method of manufacturing the semiconductor device according to the first embodiment can improve the adhesion between the side surface 22 of the circuit layer 2a and the sealing member 7 in the direction parallel to the top surface 21 of the circuit layer 2a and in the normal direction of the top surface 21 due to the anchor effect since the side surface 22 of the circuit layer 2a provided with the oxide film 6 is roughened, so as to avoid the separation of the sealing member 7.

### Second Embodiment

A semiconductor device according to a second embodiment differs from the semiconductor device according to the first embodiment in that the oxide film 6 is selectively provided at a part of the side surface 22 of the circuit layer 2a toward the top surface 21, as illustrated in FIG. 10. The oxide film 6 is provided at the upper part of the side surface 22 of the circuit layer 2a, but is not provided at the lower part of the side surface 22 of the circuit layer 2a. The upper part of the side surface 22 of the circuit layer 2a provided with the oxide film 6 is roughened, while the lower part of the side surface 22 of the circuit layer 2a is not roughened. The other configurations of the semiconductor device according to the second embodiment are substantially the same as those of the semiconductor device according to the first embodiment, and overlapping explanations are not repeated below. The semiconductor device according to the second embodiment may have a configuration in which the oxide film 6 is removed after the formation of the solder layer 4 so as not to remain on the side surface 22 of the circuit layer 2a, as in the case of the first embodiment.

A method of manufacturing the semiconductor device according to the second embodiment differs from the method of manufacturing the semiconductor device according to the first embodiment in selectively irradiating a part of the side surface 22 of the circuit layer 2a toward the top surface 21 with the laser beam. The other steps of the method of manufacturing the semiconductor device according to the second embodiment are substantially the same as those of the method of manufacturing the semiconductor device according to the first embodiment, and overlapping explanations are not repeated below.

The second embodiment, which has the structure in which the oxide film 6 is selectively provided at a part of the side surface 22 of the circuit layer 2a toward the top surface 21, can achieve the effects similar to those in the first embodiment. The second embodiment can also reduce the influence of the laser beam on the insulating substrate 1, since the side surface 22 of the circuit layer 2a is selectively irradiated with the laser beam at a part toward the top surface 21. The oxide film 6 may be selectively provided at a part of the side surface 22 of the circuit layer 2a on the side opposite to the top surface 21 (toward the insulating substrate 1), or may be provided in the middle of the side surface 22 of the circuit layer 2a.

### Third Embodiment

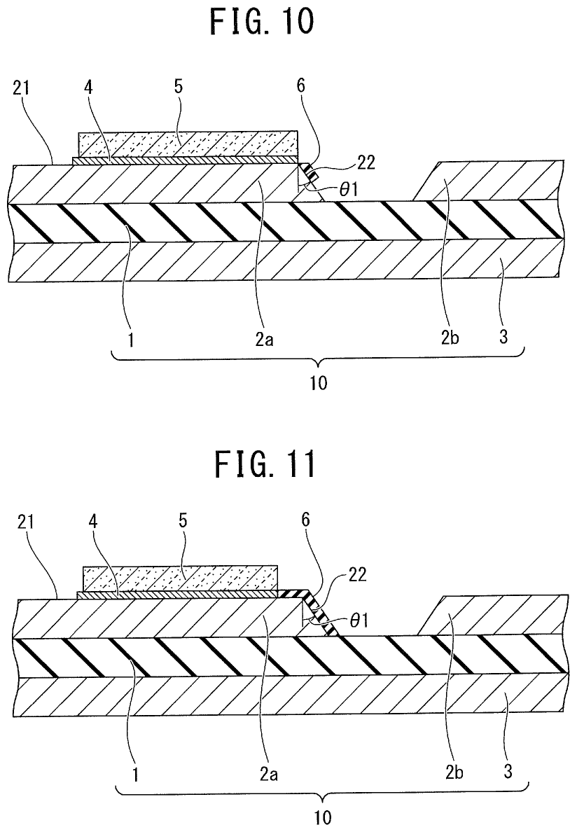

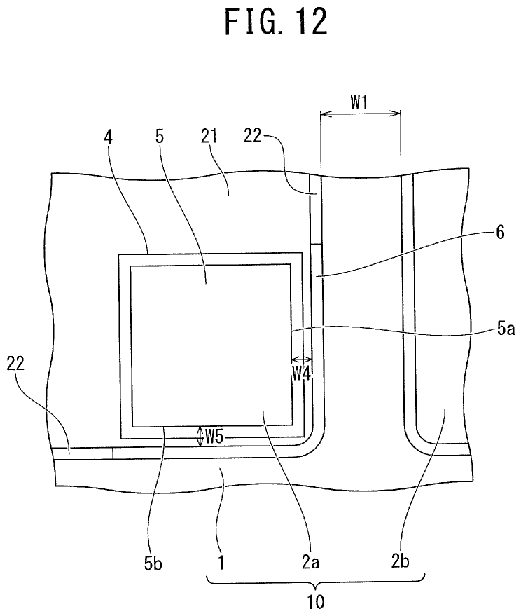

A semiconductor device according to a third embodiment differs from the semiconductor device according to the first embodiment in that the oxide film 6 is provided along a region from the side surface 22 of the circuit layer 2a continuously to a part of the top surface 21 of the circuit layer 2a, as illustrated in FIG. 11. The semiconductor chip 5 is arranged at a position separated from the edge of the top surface 21 of the circuit layer 2a. The other configurations of the semiconductor device according to the third embodiment are substantially the same as those of the semiconductor device according to the first embodiment, and overlapping explanations are not repeated below. The semiconductor device according to the third embodiment may have a configuration in which the oxide film 6 is removed after the formation of the solder layer 4 so as not to remain on the side surface 22 of the circuit layer 2a, as in the case of the first embodiment.

A method of manufacturing the semiconductor device according to the third embodiment differs from the method of manufacturing the semiconductor device according to the first embodiment in irradiating a part of the top surface 21 of the circuit layer 2a with the laser beam in addition to the side surface 22 of the circuit layer 2a. The other steps of the method of manufacturing the semiconductor device according to the third embodiment are substantially the same as those of the method of manufacturing the semiconductor device according to the first embodiment, and overlapping explanations are not repeated below.

The third embodiment with the structure in which the oxide film 6 is provided along the region from the side surface 22 of the circuit layer 2a continuously to a part of the top surface 21 of the circuit layer 2a, which slightly decreases the flexibility of the arrangement of the semiconductor chip 5, can achieve the effects similar to those in the first embodiment. The third embodiment can also avoid the spread of the solder layer 4 with higher reliability, since the part of the top surface 21 of the circuit layer 2a is provided with the oxide film 6, and the surface roughness of the part of the top surface 21 of the circuit layer 2a provided with the oxide film 6 is greater than the surface roughness of the top surface 21 of the circuit layer 2a not provided with the oxide film 6.

### Fourth Embodiment

A semiconductor device according to a fourth embodiment differs from the semiconductor device according to the first embodiment in the range provided with the oxide film 6 in the planar pattern, as illustrated in FIG. 12. The oxide film 6 is selectively provided at parts of the side surface 22 of the circuit layer 2a opposed to the right side 5a and the lower side 5b that are two continuous sides of the rectangle of the semiconductor chip 5. The semiconductor chip 5 is arranged adjacent to a corner of the top surface 21 of the circuit layer 2a. The right side 5a and the lower side 5b of the semiconductor chip 5 are separated from the edge of the top surface 21 of the circuit layer 2a with predetermined distances W4 and W5 kept. The predetermined distances W4 and W5 may be the same as or different from each other. The other configurations of the semiconductor device according to the fourth embodiment are substantially the same as those of the semiconductor device according to the first embodiment, and overlapping explanations are not repeated below. The semiconductor device according to the fourth embodiment may have a configuration in which the oxide film 6 is removed after the formation of the solder layer 4 so as not to remain on the side surface 22 of the circuit layer 2a, as in the case of the first embodiment.

A method of manufacturing the semiconductor device according to the fourth embodiment differs from the method of manufacturing the semiconductor device according to the first embodiment in selectively irradiating the parts of the side surface 22 of the circuit layer 2a opposed to the right side 5a and the lower side 5b of the semiconductor chip 5 with the laser beam. When the side surface 22 of the circuit layer 2a is irradiated with the laser beam in the normal direction of the top surface 21 of the circuit layer 2a, for example, the laser beam may be emitted continuously toward the parts opposed to the right side 5a and the lower side 5b of the semiconductor chip 5. When the side surface 22 of the circuit layer 2a is irradiated with the laser beam in the direction inclined to the normal direction of the top surface 21 of the circuit layer 2a, for example, the laser beam may be emitted two times at different irradiation angles toward the side surface 22 of the circuit layer 2a in the substantially perpendicular direction corresponding to the part opposed to the right side 5a and the part opposed to the lower side 5a of the semiconductor chip 5. The other steps of the method of manufacturing the semiconductor device according to the fourth embodiment are substantially the same as those of the method of manufacturing the semiconductor device according to the first embodiment, and overlapping explanations are not repeated below.

The fourth embodiment, which has the structure in which the oxide film 6 is selectively provided at the parts of the side surface 22 of the circuit layer 2a opposed to the right side 5a and the lower side 5b that are two continuous sides of the rectangle of the semiconductor chip 5, can achieve the effects similar to those in the first embodiment.

### OTHER EMBODIMENTS

As described above, the invention has been described according to the first to fourth embodiments, but it should not be understood that the description and drawings implementing a portion of this disclosure limit the invention. Various alternative embodiments of the present invention, examples, and operational techniques will be apparent to those skilled in the art from this disclosure.

The configurations disclosed in the first to fourth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

1. A semiconductor device comprising:
an insulated circuit substrate including a circuit layer having a main surface and a side surface inclined to a normal direction of the main surface;
a semiconductor chip provided to be opposed to the main surface of the circuit layer; and
a solder layer provided to bond the semiconductor chip and the circuit layer to each other,
wherein a surface roughness of at least a part of the side surface of the circuit layer is greater than a surface roughness of the main surface of the circuit layer at a position opposed to the semiconductor chip.

2. The semiconductor device of claim 1, further comprising an oxide film provided at least at a part of the side surface of the circuit layer.

3. The semiconductor device of claim 2, wherein a thickness of the oxide film is two nanometers or greater.

4. The semiconductor device of claim 1, further comprising a sealing member provided to seal the semiconductor chip.

5. A method of manufacturing a semiconductor device, comprising;
preparing an insulated circuit substrate including a circuit layer having a main surface and a side surface inclined to a normal direction of the main surface;
irradiating the side surface of the circuit layer with a laser beam so as to roughen at least a part of the side surface of the circuit layer and provide an oxide film on the roughened side surface of the circuit layer; and
bonding a semiconductor chip to the main surface of the circuit layer via a solder layer.

6. The method of claim 5, wherein the laser beam is emitted in a direction inclined toward a normal direction of the side surface of the circuit layer with respect to the normal direction of the main surface of the circuit layer.

7. The method of claim 5, wherein a thickness of the oxide film when formed is 50 nanometers or greater.

8. The method of claim 5, wherein an arithmetic mean roughness of at least the part of the side surface of the circuit layer is 25 micrometers or greater.

9. The method of claim 5, wherein an angle of the side surface inclined to the normal direction of the main surface of the circuit layer is in a range of greater than 0 degrees and 45 degrees or smaller.

10. The method of claim 5, wherein a part of the side surface of the circuit layer toward the main surface is roughened.

11. The method of claim 5, wherein a region from the side surface to a part of the main surface of the circuit layer is roughened.

12. The method of claim 5, wherein:
the semiconductor chip has a rectangular shape in a planar pattern; and
one side of the semiconductor chip is arranged at an edge of the main surface of the circuit layer.

13. The method of claim 5, wherein:
the semiconductor chip has a rectangular shape in a planar pattern; and
a part of the side surface of the circuit layer opposed to one side of the semiconductor chip is selectively roughened.

14. The method of claim 5, wherein:
the semiconductor chip has a rectangular shape in a planar pattern; and
parts of the side surface of the circuit layer opposed to two continuous sides of the semiconductor chip are selectively roughened.
